(19) United States
(12) Patent Application Publication
(10) Pub. No.: US 2020/0256895 A1
(43) Pub. Date: Aug. 13, 2020

(54) ELECTRIC CURRENT SENSOR

(71) Applicant: Hitachi Metals, Ltd., Tokyo (JP)

(72) Inventors: Ken OKUYAMA, Tokyo (JP); Akitoshi Fujimori, Tokyo (JP); Naoki Futakuchi, Tokyo (JP); Yujiro Tomita, Tokyo (JP); Jun Umetsu, Tokyo (JP)

(21) Appl. No.: 16/783,887

(22) Filed: Feb. 6, 2020

(30) Foreign Application Priority Data
Feb. 12, 2019 (JP) 2019-022664

(51) Int. Cl. G01R 15/14; G01R 19/00

(52) U.S. Cl. CPC G01R 15/148; G01R 19/0092

(57) ABSTRACT

An electric current sensor includes bus bars each having a plate shape through which an electric current to be detected flows in a length direction, a housing including a bus bar-holding portion for holding the bus bars with being aligned in a width direction perpendicular to the length direction and a thickness direction of the bus bars, magnetic detection elements, each of which detects a strength of magnetic field generated by the electric current flowing through a corresponding bus bar, and a first shield plate and a second shield plate arranged to sandwich the respective bus bars and the magnetic detection elements in the thickness direction. Each of the first shield plate and the second shield plate is made of a magnetic material. Both the first shield plate and the second shield plate are held directly and commonly by the housing.

### CROSS-REFERENCE TO RELATED APPLICATIONS

The present invention is based on Japanese Patent Application No. 2019-22664 filed on Feb. 12, 2019, the entire contents of which are incorporated herein by reference.

### BACKGROUND OF THE INVENTION

### 1. Field of the Invention

The present invention relates to an electric current sensor.

### 2. Description of the Related Art

Conventionally, as an electric current sensor, those having a magnetic detection element for detecting the strength of the magnetic field generated by the electric current to be detected have been known (e.g., see JP2018-96795A). By detecting the strength of the magnetic field by the magnetic detection element, based on the strength of the magnetic field, it is possible to determine the electric current by the computation.

[Patent Document 1] JP2018-96795A

### SUMMARY OF THE INVENTION

For example, when detecting an electric current flowing through each of the plurality of bus bars, the magnetic detection element is provided to correspond to each bus bar. At this time, if the magnetic field generated by the electric current flowing through the bus bar other than the bus bar corresponding to the magnetic detection element is detected at the magnetic detection element, it may cause an error.

Accordingly, it is an object of the present invention to provide an electric current sensor capable of detecting the electric current with high accuracy.

The present invention, for the purpose of solving the above problems, provides:

an electric current sensor comprising:

bus bars, each of which has a plate shape and flows an electric current to be detected in a length direction;

a housing including a bus bar-holding portion for holding the bus bars with being aligned in a width direction perpendicular to the length direction and a thickness direction of the bus bars;

magnetic detection elements, each magnetic detection element detecting a strength of magnetic field generated by the electric current flowing through a corresponding bus bar; and

a first shield plate and a second shield plate arranged to sandwich the respective bus bars and the magnetic detection elements in the thickness direction, each of the first shield plate and the second shield plate comprising a magnetic material,

wherein both the first shield plate and the second shield plate are held directly and commonly by the housing.

### Points of Invention

According to the present invention, it is possible to provide an electric current sensor capable of detecting the electric current with high accuracy.

### BRIEF DESCRIPTION OF THE DRAWINGS

FIG. 1A is a perspective view showing an electric current sensor according to one embodiment of the present invention.

FIG. 1B is a cross-sectional view of the electric current sensor taken along A-A line in FIG. 1A.

FIG. 2 is an exploded perspective view of the electric current sensor in FIG. 1A.

FIG. 3 is an exploded perspective view of the electric current sensor in FIG. 1A.

FIG. 4A is an upper perspective view of a housing.

FIG. 4B is a lower perspective view of the housing.

FIG. 5A is a perspective view when placing bus bars in the housing.

FIG. 5B is a perspective view when placing the bus bars and a spacer in the housing. FIG. 6A is a perspective view when a lid is fixed by screwing to the housing.

FIG. 6B is a cross-sectional view taken along B-B line in FIG. IA.

FIG. 7A is a diagram showing a simulated result of the direction of the magnetic field generated when the electric current flows only to the bus bar of the U phase in the electric current sensor.

FIG. 7B is an explanatory view of the deflection of the substrate when the electric current flows only to the bus bar of the U phase in the electric current sensor.

FIG. 8A is a cross-sectional view when tilting the second shield plate.

FIG. 8B is a graph showing a width direction component of the magnetic flux density at the magnetic detection element arrangement position, when passing the electric current to the U phase in FIG. 8A.

FIG. 8C is a graph showing a width component of the magnetic flux density at the magnetic detection element arrangement position, when passing the electric current to the V phase in FIG. 8A.

### DETAILED DESCRIPTION OF THE PREFERRED EMBODIMENT

### Embodiment

Next, the embodiment of the present invention will be described in accordance with the appended drawings.

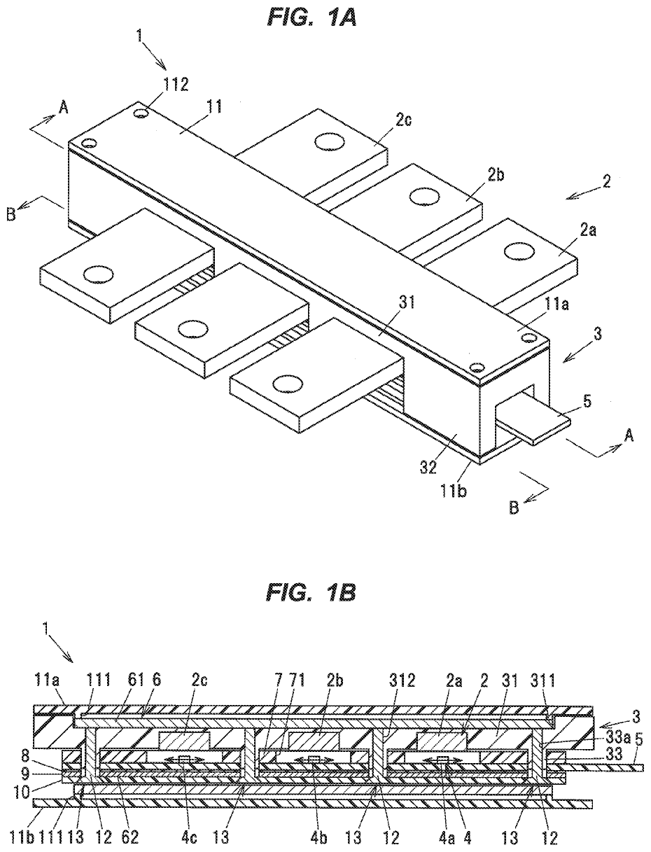

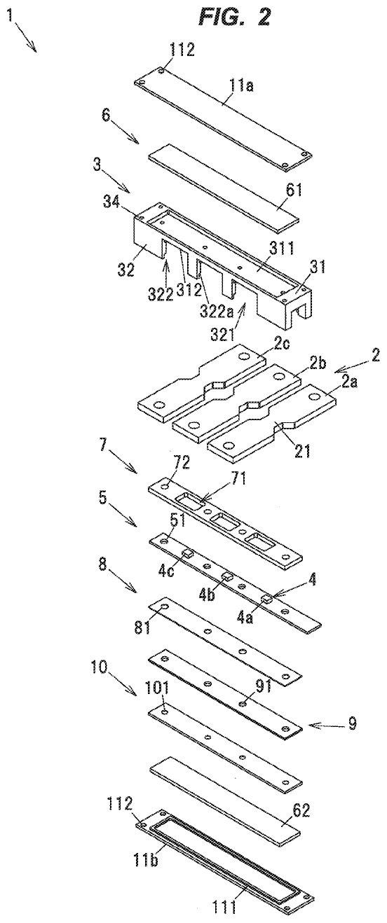

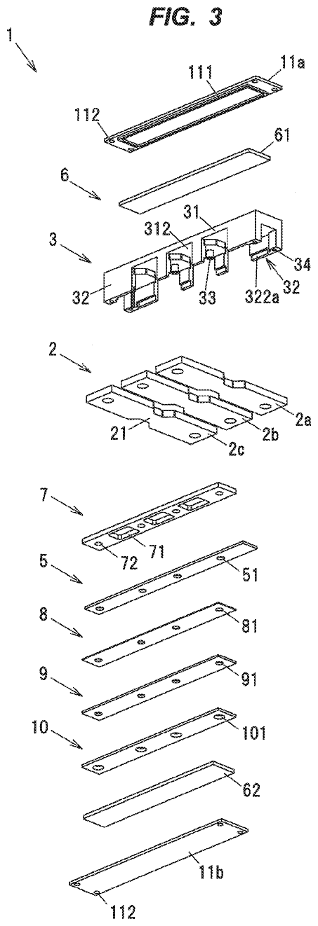

FIG. 1A is a perspective view showing an electric current sensor 1 according to one embodiment of the present invention. FIG. 1B is a cross-sectional view of the electric current sensor 1 taken along A-A line in FIG. 1A. FIG. 2 is an exploded perspective view of the electric current sensor 1 in FIG. 1A. FIG. 3 is an exploded perspective view of the electric current sensor 1 in FIG. 1A.

As shown in FIGS. 1A to 1C, 2 and 3, the electric current sensor 1 includes a plurality of bus bars 2, a housing 3, a plurality of magnetic detection elements 4, a substrate 5, a pair of shield plates 6, a spacer 7, a substrate side spacer 8, a conductive plate 9, a lid 10, and a pair of shield covers 11.

The bus bar 2 is formed in a plate shape, and the electric current to be detected flows in its length direction. The bus bar 2 is made of, e.g., copper or copper alloy. In the present embodiment, three bus bars 2a to 2c for flowing the electric current of three phases of U phase, V phase, and W phase, respectively are used. The three bus bars 2a to 2c are held in the housing 3 in a state of being aligned in the width direction. Hereinafter, when the direction is referred to as merely “the length direction”, “the thickness direction”, or “the width direction”, it means the length direction, the thickness direction, or the width direction of the bus bar 2.

The bus bar 2 includes, in a portion of its length direction (here a central portion in the length direction), a narrow width portion 21 with a reduced width. In the electric current sensor 1, the magnetic detection element 4 is arranged in such a manner as to face the narrow width portion 21 in the thickness direction. The narrow width portion 21 serves to suppress the influence of the skin effect at high frequencies, thereby contributing to the improvement of detection accuracy. More specifically, when the electric current of the high frequency flows to the bus bar 2, the electric current distribution by the skin effect is biased to the surface of the bus bar 2. Since the skin thickness varies depending on the frequency and the electric current distribution inside the bus bar 2 varies, the magnetic flux density at the position of the magnetic detection element 4 varies. When placing the magnetic detection element 4 in such a manner as to face the central portion in the width direction of the bus bar 2, as viewed from the magnetic detection element 4 side, in a position where the aspect ratio of the cross-sectional shape of the energized surface of the bus bar 2 is small, the spread of the electric current distribution (i.e. frequency dependency of the electric current distribution) is reduced. Thus, the influence of the skin effect is considered to be reduced.

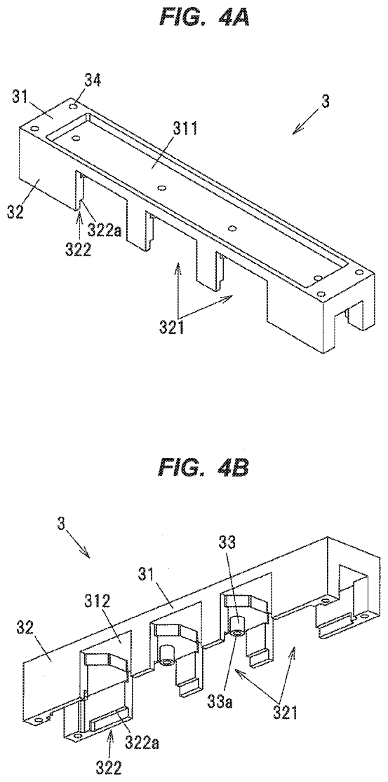

FIG. 4A is an upper perspective view of the housing 3. FIG. 4B is a lower perspective view of the housing 3. The housing 3 is made of a resin molded body of PPS (polyphenylene sulfide), PPA (polyphthalamide) or the like. The housing 3 is provided parallel to the bus bar 2, and includes an upper wall 31 formed in a rectangular shape having a pair of long sides facing each other in the length direction and a pair of short sides facing each other in the width direction in planar view, and a pair of side walls 32 extended in the thickness direction from edges of the long sides in the upper wall 31. The upper wall 31 is provided to be parallel to the bus bar 2.

At an upper surface of the upper wall 31 (the surface opposite to the bus bar 2), a recess 311 for accommodating a first shield plate 61 to be described later is formed. Further, at a lower surface of the upper wall 31 (the surface on the bus bar 2 side), three concave bus bar-holding portions 312 for accommodating the bus bars 2 respectively are formed. Each of the bus bar-holding portions 312 is formed in substantially the same shape as the bus bar 2 in planar view (the same shape as the narrow width portion 21 and its surrounding bus bar 2). Hereinafter, when the direction is referred to as merely “upward” or “downward”, it means upward or downward in FIG. 2. It should be noted that the terms “upward” and “downward” are used for convenience, and they do not mean the vertical direction in the use state of the electric current sensor 1.

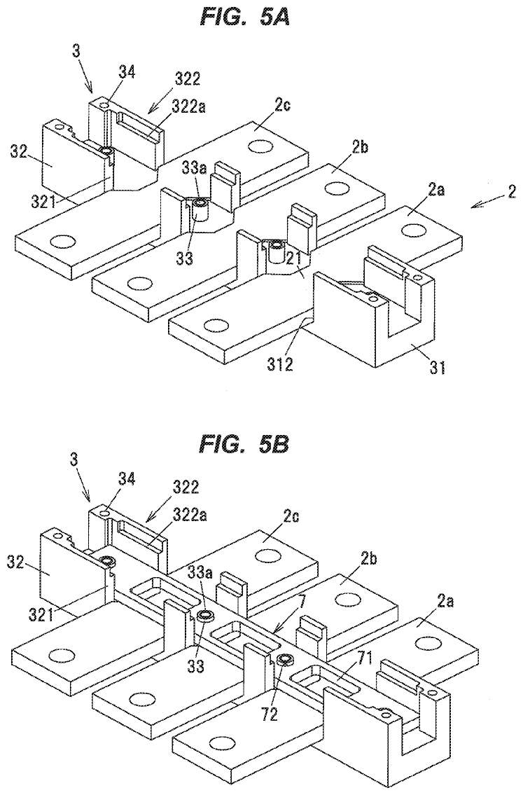

As shown in FIG. 5A, by accommodating each bus bar 2 in the bus bar-holding portion 312, the positioning of the bus bars 2 for the housing 3 is performed, and the bus bars 2 are held in the housing 3 in the state of being aligned in the width direction. The depth of the bus bar-holding portion 312 is smaller than the thickness of the bus bar 2. Thus, a portion in the thickness direction of the bus bar 2 protrudes from the lower surface of the upper wall 31.

Further, a cylindrical protrusion 33 formed with a screw hole 33a for screwing a screw 12 to be described later is provided as a portion protruding downward from the lower surface of the upper wall 31. The protrusions 33 are provided between the both ends in the width direction and between the adjacent bus bar-holding portions 312, respectively, and four protrusions 33 in total are provided. The protrusions 33 constitute a part of a fixing portion 13 to be described later.

At each of the two side walls 32, three notches 321 corresponding to the three bus bar-holding portions 312 are formed for guiding each bus bar 2 to the bus bar-holding portion 312 of the upper wall 31 (i.e. inserting the bus bar 2 into the upper wall 31 side). The notches 321 are formed to be spaced from each other in the width direction, and formed to open downward (toward a tip end side of the side wall 32). The bus bar 2 is provided to the bus bar-holding portion 312 through the notch 321 from below.

Further, at each of the tip ends of the two side walls 32 (lower end), a step portion 322 for accommodating a second shield plate 62 to be described later is formed. The step portion 322 is formed by protruding an outer peripheral portion of the side wall 32 downward (tip end side) and recessing an inner peripheral portion of the side wall 32 upward (upper wall 31 side). A step surface 322a is formed to be parallel to a bottom surface of the recess 311 in the upper wall 31 (or a surface of the first shield plate 61 held in the recess 311) and a bottom surface of the bus bar-holding portion 312 (or a surface of the bus bar 2 held in the bus bar-holding portion 312). The second shield plate 62 to be described later is held by the step surfaces 322a.

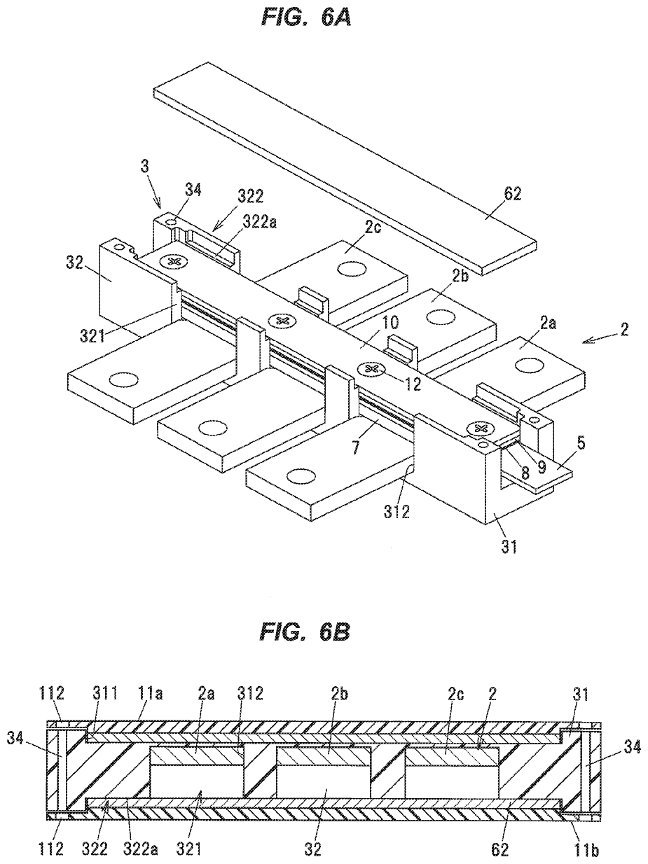

At four corners of the housing 3 in the upper surface view, bolt holes 34 are formed to penetrate through the upper wall 31 and the side walls 32 in the thickness direction (see FIG. 6B). The bolt hole 34 is used to pass through a bolt (not shown) for fixing the shield cover 11.

The magnetic detection element 4 is provided for detecting the strength of the magnetic field generated by the electric current flowing through the bus bar 2, and is configured to output a signal of the voltage corresponding to the strength of the magnetic field (magnetic flux density) in the direction along the magnetic detection axis D. The magnetic detection element 4 is made of a Hall element, a GMR (Giant Magneto Resistive effect) element, or the like. Here, the magnetic detection element 4 including a Hall element is used. In the electric current sensor 1, the magnetic detection elements 4 with the same number as the bus bars 2 for flowing the electric current to be detected are used. Here, three magnetic detection elements 4a to 4c are used in response to the three bus bars 2a to 2c.

The respective magnetic detection elements 4 are provided in such a manner as to face the corresponding bus bars 2 in the thickness direction. More specifically, each magnetic detection element 4 is provided in such a manner as to face the narrow width portion 21 of the bus bar 2, and the width direction center of the narrow width portion 21 and a magnetic detection unit (sensing unit) of the magnetic detection element 4 are provided in such a manner as to face each other in the thickness direction.

The three magnetic detection elements 4 are mounted on a single common substrate 5. Further, each magnetic detection element 4 is configured to detect a magnetic field in a direction parallel to the surface (mounting surface) of the substrate 5. The substrate 5 is formed in a rectangular plate shape having a pair of long sides facing each other in the length direction and a pair of short sides facing each other in the width direction in planar view. The substrate 5 is arranged to sandwich the three bus bars 2 between the upper wall 31 of the housing 3 and the substrate 5. The three magnetic detection elements 4, on the surface of the substrate 5 (the surface of the bus bar 2 side), are arranged to be aligned in a row along the width direction. Although not shown, the substrate 5 is provided with a connector, and is configured to connect to an external computing device or power supply via this connector. Further, the substrate 5 is provided with four through-holes 51 for passing the protrusions 33 therethrough.

Between the bus bars 2 and the substrate 5, the spacer 7 is provided. The spacer 7 formed in a rectangular plate shape having a pair of long sides facing each other in the length direction and a pair of short sides facing each other in the width direction in planar view. The spacer 7 is provided with housing holes 71 for accommodating the magnetic detection elements 4 to penetrate through the spacer 7 in the thickness direction. Further, the spacer 7 is provided with four through-holes 72 for passing the protrusions 33 therethrough. The spacer 7 serves to space the bus bars 2 from the substrate 5 while keeping a constant distance between the bus bars 2 and the substrate 5, i.e. a constant distance between the bus bars 2 and the magnetic detection elements 4.

FIG. 5B is a perspective view when placing the bus bars 2 and the spacer 7 in the housing 3. As described above, since each bus bar 2 is arranged to protrude from the lower surface of the upper wall 31, the spacer 7 is configured to contact directly (surface contact) with the surface on the substrate 5 side of each bus bar 2. The substrate 5 is arranged in such a manner that the surface on which the magnetic detection elements 4 are mounted is provided as the bus bar 2 side, in a state of accommodating each magnetic detection element 4 in the housing hole 71. That is, the substrate 5 is arranged in such a manner that the surface on which the magnetic detection elements 4 are mounted contacts directly with the spacer 7. The spacer 7 is made of a resin molded body of PPS, PPA or the like. Positioning of the spacer 7 and the substrate 5 (magnetic detection element 4) with respect to the housing 3 and the bus bars 2 is performed by passing the protrusions 33 through the through-holes 72 of the spacer 7 and the through-holes 51 of the substrate 5.

On the opposite side of the substrate 5 with respect to the spacer 7, the substrate side spacer 8, the conductive plate 9 made of a non-magnetic material, and the lid 10 are sequentially provided. The substrate side spacer 8 serves to space the substrate 5 from the conductive plate 9, while keeping a constant distance between the substrate 5 and the conductive plate 9. The substrate side spacer 8 is formed in a rectangular plate shape having a pair of long sides facing each other in the length direction and a pair of short sides facing each other in the width direction in planar view. Further, the substrate side spacer 8 is provided with four through-holes 81 for passing the screws 12 therethrough. The substrate side spacer 8 is made of a resin molded body of PPS, PPA or the like.

The conductive plate 9 is provided for changing the frequency characteristic of the strength of the magnetic field detected by the magnetic detection element 4 under the influence of the eddy current generated in the conductive plate 9, thereby improving the responsiveness to the electric current (pulse response). The conductive plate 9 is made of a non-magnetic conductive material such as copper or aluminum. The conductive plate 9 is formed in a rectangular plate shape having a pair of long sides facing each other in the length direction and a pair of short sides facing each other in the width direction in planar view. Further, the conductive plate 9 is arranged in such a manner that the surface of the conductive plate 9 is parallel to the surface of the bus bar 2. The conductive plate 9 is provided with four through-holes 91 for passing the screws 12 there through. It should be noted that the conductive plate 9 and the substrate side spacer 8 are optional for the case of using the electric current sensor 1 in applications where the responsiveness to current is not required.

The lid 1 is formed in a rectangular plate shape having a pair of long sides facing each other in the length direction and a pair of short sides facing each other in the width direction in planar view. The lid 10 is provided to sandwich the bus bars 2, the spacer 7, the substrate 5, the substrate side spacer 8, and the conductive plate 9 in the thickness direction between the upper wall 31 of the housing 3 and the lid 10. The lid 10 is provided with four through-holes 101 for passing the screws 12 therethrough. The lid 10 is made of a resin molded body of PPS, PPA or the like.

As shown in FIG. 6A, the bus bars 2, the spacer 7, the substrate 5, the substrate side spacer 8 and the conductive plate 9 are sandwiched and fixed between the upper wall 31 of the housing 3 and the lid 10, by inserting the screws 12 through the through-holes 101 of the lid 10 and screwing the screws 12 to the screw holes 33a of the protrusions 33.

A pair of shield plates 6 are provided for shielding the magnetic field from the outside in such a manner that the magnetic field from the outside would not affect the detection result of the magnetic detection element 4. The pair of shield plates 6 are provided to sandwich the housing 3, the bus bars 2, the spacer 7, the substrate 5 (the magnetic detection elements 4), the substrate side spacer 8, the conductive plate 9, and the lid 10 in the thickness direction between the upper wall 31 of the housing 3 and the pair of shield plates 6. Further, both shield plates 6 are arranged in such a manner that the surfaces of the shield plates 6 are parallel to the surface of the bus bar 2. Each of the shield plates 6 is made of a magnetic material formed in a rectangular plate shape having a pair of long sides facing each other in the length direction and a pair of short sides facing each other in the width direction in planar view. Hereinafter, the shield plate 6 on the bus bar 2 side is referred to as the first shield plate 61, and the shield plate 6 on the substrate 5 side (lid 10 side) is referred to as the second shield plate 62.

As shown in FIGS. 1A and 6B, the first shield plate 61 is accommodated in the recess 311 at the upper wall 31 of the housing 3. An opening of the recess 311 is closed (covered) by one of the shield covers 11, so that the first shield plate 61 is held in the recess 311. Hereinafter, the shield cover 11 provided on the upper wall 31 side is referred to as a first shield cover 11a, while the shield cover 11 provided on the lower end side of the side wall 32 is referred to as a second shield cover 11b. Each of the shield covers 11 is formed in a rectangular plate shape having a pair of long sides facing each other in the length direction and a pair of short sides facing each other in the width direction in planar view. At the edge of one surface of the shield cover 11, a rectangular frame-shaped pressing rib 111 protruding in a substantially perpendicular direction from the surface is formed. The first shield plate 61 is held in a state of being pressed against the bottom surface of the recess 311 by the pressing ribs 111 of the first shield cover 11a.

The second shield plate 61 is held by the step portions 322 at the side walls 32 of the housing 3. At the tip ends of the two side walls 32, the second shield cover 11b is provided to face the upper wall 31. The second shield plate 62 is held in a state of being pressed against the step surfaces 322a by the pressing ribs 111 of the second shield cover 11b.

The shield cover 11 is made of a resin molded body of PPS, PPA or the like. In vicinity of the four corners of each of both the shield covers 11, bolt holes 112 for passing bolts (not shown) therethrough for fixing the shield cover 11 to the housing 3 are formed. The shield covers 11 are fixed to the housing 3 by passing the bolts through the bolt holes 112 of both the shield covers 11 and the bolt holes 34 of the housing 3, then by fastening and fixing both the shield covers 11 to sandwich the housing 3 between both the shield covers 11. Here, although the first shield cover 11a and the second shield cover 11b are formed to have the same shape for trying to reduce the cost, the present invention is not limited thereto. The shapes of the first shield cover 11a and the second shield cover 11b may be different from each other.

### Configuration for Keeping the Bus Bars 2 and the Substrate 5 Parallel

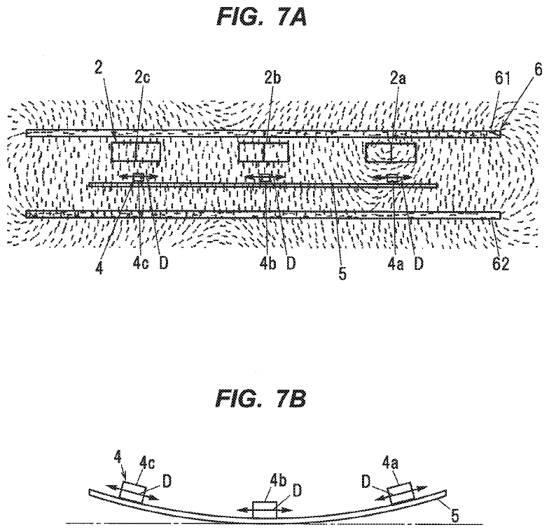

FIG. 7A is a diagram showing a simulated result of the direction of the magnetic field generated when the electric current flows only to the bus bar 2a of the U phase in the electric current sensor 1. As shown in FIG. 7A, the orientation of the magnetic field generated in the bus bar 2a of the U phase is in the direction along the width direction at the position of the magnetic detection element 4a of the U phase (lateral direction in FIG. 7A). The orientation of the magnetic field generated in the bus bar 2a of the U phase is in the direction along the thickness direction (vertical direction) at the position of the magnetic detection elements 4b, 4c of the other phases (V phase, W phase). In the magnetic detection element 4, since the magnetic field in the direction perpendicular to the direction of the magnetic detection axis D is not detected, it is possible to suppress the influence of the magnetic field of the other phases, by arranging the magnetic detection axis D of each magnetic detection element 4 in the direction along the width direction.

Here, as described above, the magnetic detection element 4 is configured to detect the magnetic field in a direction parallel to the surface (mounting surface) of the substrate 5. Therefore, as shown in FIG. 7B, when the warping or deflection is present in the substrate 5, the magnetic detection axis D of the magnetic detection element 4 will be tilted upward or downward with respect to the width direction, so that the magnetic detection element 4 becomes susceptible to the influence of the magnetic field generated by the electric current of the other phase. However, it is inevitable that a slight warp or deflection would occur in the substrate 5 in the production of the electric current sensor, and the countermeasures are required.

Therefore, in the electric current sensor 1 according to the present embodiment, the fixing portions 13 for fixing the substrate 5 to the housing 3 are provided at both ends of the substrate 5 in the width direction and at least one location between the magnetic detection elements 4 adjacent to each other in the width direction. For example, when fixing only both ends of the substrate 5 in the width direction to the housing 3, floating may occur in the central portion of the substrate 5 in the width direction, so that the magnetic detection axis D of the magnetic detection element 4 may tilt upward or downward with respect to the width direction. Therefore, by providing fixing portions 13 at locations between the adjacent magnetic detection elements 4 in addition to the both ends of the substrate 5 in the width direction, it is possible to correct the warping or deflection of the substrate 5, thereby forcing the substrate 5 to hold in a parallel state with the bus bars 2. Thus, since the magnetic detection axis D of the magnetic detection element 4 is maintained in the direction along the width direction, each magnetic detection element 4 is less susceptible to the influence of the magnetic field generated in the other phase.

Further, from the viewpoint of holding the substrate 5 in a flatter state, it can be said that the number of the fixing portions 13 is preferably increased as much as possible. Therefore, more preferably, the fixing portions 13 may be provided in each of both ends of the substrate 5 in the width direction and between the magnetic detection elements 4 adjacent to each other in the width direction. Here, two fixing portions 13 are provided between the magnetic detection element 4a of the U phase and the magnetic detection element 4b of the V phase, and between the magnetic detection element 4b and of the V phase and the magnetic detection element 4c of the W phase, respectively. Therefore, together with the two fixing portions 13 provided to sandwich the magnetic detection elements 4a to 4c, four fixing portions 13 in total are provided.

In the present embodiment, the fixing portion 13 has a configuration that a screw 12 is screwed to the hole 33a of the protrusion 33 in the housing 3. However, the specific configuration of the fixing portion 13 is not limited thereto. For example, the fixing portion 13 may have a configuration that the protrusion 33 in the housing 3 is formed to have a sufficient length for contacting with the lid 10, and a contact portion between the tip end portion of the protrusion 33 and the lid 10 is fixed with a hot caulking. Further, for example, the fixing portion 13 may have a configuration including an engaging portion for engaging the substrate 5 to the housing 3, or the like.

Further, in the present embodiment, the lid 10 is fixed by screwing to the housing 3, the bus bars 2 and the substrate 5 are sandwiched between the housing 3 and the lid 10, thereby providing the fixing portion 13. Thus, it is possible to suppress that the substrate 5 is damaged by the screw 12. Further, by pressing on the surface of the substrate 5 by the lid 10, it is possible to further enhance the flatness of the substrate 5. Still further, since the bus bars 2 and the conductive plate 9 can also be fixed collectively by the lid 10, it is not necessary to separately provide a member for fixing the bus bars 2 and the conductive plate 9. It should be noted that the present invention is not limited thereto. It is also naturally possible to configure the fixing portion 13 to fix the substrate 5 directly to the upper wall 31 of the housing 3.

As shown in FIG. 7A, the direction of the magnetic field is likely to be most aligned to the thickness direction (the direction perpendicular to the magnetic detection axis D) at an intermediate position of both the shield plates 6 in the thickness direction, i.e. at a position which is equidistant from both the shield plates 6. Therefore, it is preferable to place the respective magnetic detection elements 4 at positions which are equidistant from both the shield plates 6.

Further, by providing the plate-like spacer 7 between a plurality of bus bars 2 and the substrate 5, it is possible to space the bus bars 2 from the substrate 5 while maintaining a constant distance between the bus bars 2 and the substrate 5 (magnetic detection elements 4). Thus, it is possible to perform high-precision current detection by keeping the distance between the bus bars 2 and each magnetic detection element 4 accurately at a desired distance. Further, by providing a configuration that the bus bars 2 protrude from the upper wall 31 (bus bar-holding portion 312) of the housing 3, and that the spacer 7 directly contacts with the surface on the substrate 5 side of each bus bar 2, the bus bars 2 and the spacer 7 can be maintained in parallel. Further in this state, by providing a configuration that the spacer 7 directly contacts with the substrate 5, the bus bars 2 and the substrate 5 can be maintained to be parallel to each other via the spacer 7. As a result, the magnetic detection axis D of the magnetic detection element 4 is easily maintained in the direction along the width direction, so that each magnetic detection element 4 is less susceptible to the influence of the magnetic field generated in the other phase.

### Configuration for Keeping the Shield Plates 6 Parallel to Each Other

As shown in FIG. 7A, when passing an electric current to any phase, at a position distant in the width direction from the phase through which the electric current is flowed, the magnetic field is likely to be generated in a vertical direction with respect to the surface of the shield plate 6. Therefore, when both the shield plates 6 are not parallel to each other and relatively tilted from each other, the orientation of the magnetic field at the position of the magnetic detection element 4 of the other phase will be tilted with respect to the thickness direction (the direction perpendicular to the magnetic detection axis D), so that each magnetic detection element 4 may be susceptible to the influence of the magnetic field generated by the other phase.

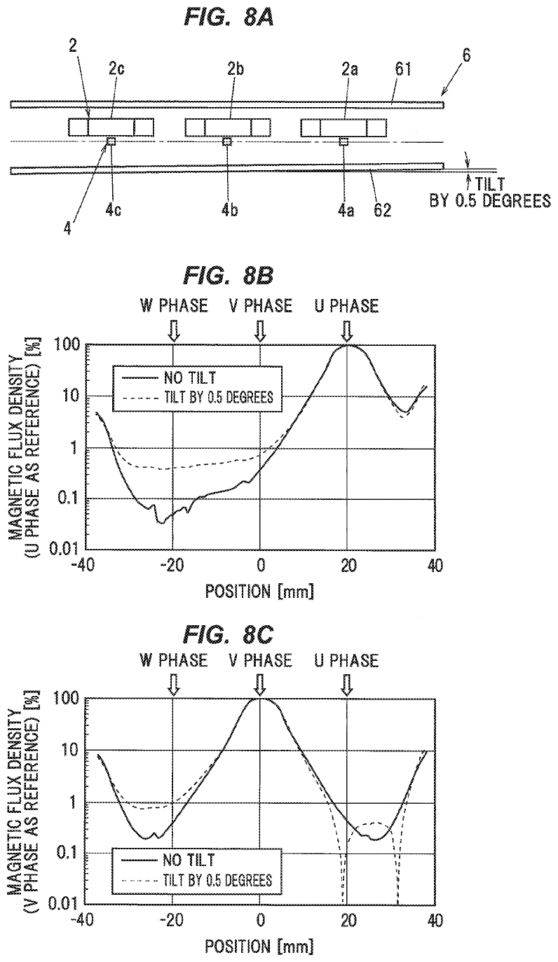

As an example, referring to FIG. 8A, the case where the second shield plate 62 is tilted by 0.5 degrees with respect to the width direction will be examined below. In this case, FIG. 8B shows a simulated result of the magnetic flux density in the width direction when passing the electric current to the bus bar 2a of the U phase, and FIG. 8C shows a simulated result of the magnetic flux density in the width direction (width direction component of the magnetic flux density) when passing the electric current to the bus bar 2b of the V phase. FIGS. 8B and 8C show the distribution of the width direction component of the magnetic flux density at the position for placing the magnetic detection elements 4 which is shown by a single-dot chain line in FIG. 8A, as well as the ratio of the magnetic flux density wherein the maximum magnetic flux density (magnetic flux density immediately below the phase flowing the electric current) is 100%. Further, FIGS. 8B and 8C also show the simulated results in the case where the second shield plate 62 is not tilted (no tilt) with respect to the width direction.

As shown in FIG. 8B, when the electric current is flowed to the U phase, due to the second shield plate 62 being tilted, the magnetic flux density detected by the magnetic detection elements 4b, 4c is increased for both the V phase and W phase. It can be understood that the magnetic detection element 4a is susceptible to the influence of the magnetic field generated in the other phases. Further, as shown in FIG. 8C, when the electric current is flowed to the V phase, although the magnetic flux density detected by the magnetic detection element 4a of the U phase is reduced, the magnetic flux density detected by the magnetic detection element 4c of the W phase is increased significantly. Thus, also in this case, the magnetic detection element 4b is susceptible to the influence of the magnetic field generated in the other phases. Depending on the interval between the bus bars 2 (the interval between the magnetic detection elements 4), one of the pair of shield plates 6 is tilted by 0.5 degrees, the interference to the adjacent phase may be increased by about 3%. Therefore, it is desirable to arrange the shield plates 6 to be parallel to each other.

Therefore, in the electric current sensor 1 according to the present embodiment, the housing 3 is configured to hold both the first shield plate 61 and the second shield plate 62 directly. For example, in a configuration that a laminate is formed by laminating a plurality of members, and then the first shield plate 61 is provided at one end of the laminate and the second shield plate 62 at the other end of the laminate to sandwich the laminate between the first shield plate 61 and the second shield plate 62, it will be difficult to hold the first shield plate 61 and the second shield plate 62 parallel, due to the influence of the accumulated manufacturing tolerances of the respective members constituting the laminate. As in the present embodiment, by providing a configuration for directly holding both the first and second shield plates 61, 62 by the housing 3 as one member, only the manufacturing tolerance of the housing 3 will affect the parallelism of the first and second shield plates 61, 62, so that it is possible to hold the first and second shield plates 61, 62 accurately parallel. As a result, when passing the electric current to any phase, the orientation of the magnetic field at the position of the magnetic detection element 4 of the other phase can be aligned to the thickness direction (direction perpendicular to the magnetic detection axis D), so that each magnetic detection element 4 is less susceptible to the influence of the magnetic field generated by the other phase.

When the lid 10 protrudes downward (the tip end side of the side wall 32) with respect to the step surfaces 322a, the second shield plate 62 will float from the step surfaces 322a, so that the shield plates 6 may not be held parallel to each other. Therefore, as shown in FIG. 6A, it is configured in such a manner that the lid 10 is located above (on the upper wall 31 side) the step surfaces 322a in a state where the lid 10 is fixed by the screws 12. Therefore, in the state where the second shield plate 62 is held by the step surfaces 322a, the second shield plate 62 is not in contact with the lid 10 and a slight gap is present between the second shield plate 62 and the lid 10. The positioning of the lid 10 in the thickness direction can be appropriately adjusted by the thickness of the substrate side spacer 8, the conductive plate 9, or the lid 10.

Further, in the present embodiment, the second shield plate 62 is held by the side walls 32 at the both ends in the width direction and the side walls 32 between the notches 321 adjacent to each other in the width direction. For example, it is also possible to provide the three notches 321 as one member and to hold only both ends of the second shield plate 62 in the width direction by the side walls 32. However, in this case, the central portion of the second shield plate 62 may be deflected. As in the present embodiment, by a configuration that not only the width direction both ends but also the central portion in the width direction of the second shield plate 62 are held by the side walls 32, it is possible to suppress the deflection of the second shield plate 62, thereby to hold the both shield plates 6 more parallel.

Furthermore, in the present embodiment, since the housing 3 is configured to directly hold the bus bars 2, it is possible to hold the bus bars 2 and the both shield plates 6 parallel with high accuracy.

### Advantageous Effect of the Embodiment

As described above, in the electric current sensor 1 according to the present embodiment, both the first shield plate 61 and the second shield plate 62 are directly held by the common housing 3. By holding the both shield plates 6 directly with the same member (housing 3), it is less susceptible to the manufacturing tolerances, and it is possible to keep the first shield plate 61 and the second shield plate 62 parallel with high accuracy. As a result, it is possible to suppress the influence of the magnetic field generated by the other phase in each magnetic detection element 4, thereby to achieve the electric current sensor 1 capable of detecting the electric current with high accuracy.

### Summary of the Embodiment

Next, the technical thought grasped from the embodiment described above, described by incorporating the code or the like in the embodiment. However, each code or the like in the following description is not limited to the member or the like specifically shown in the embodiment of the components in the claims.

[1] An electric current sensor (1) comprising:

bus bars (2), each of which has a plate shape and flows an electric current to be detected in a length direction;

a housing (3) including a bus bar-holding portion (312) for holding the bus bars (2) with being aligned in a width direction perpendicular to the length direction and a thickness direction of the bus bars (2);

magnetic detection elements (4), each magnetic detection element (4) detecting a strength of magnetic field generated by the electric current flowing through a corresponding bus bar (2); and

a first shield plate (61) and a second shield plate (62) arranged to sandwich the respective bus bars (2) and the magnetic detection elements (4) in the thickness direction, each of the first shield plate (61) and the second shield plate (62) comprising a magnetic material,

wherein both the first shield plate (61) and the second shield plate (62) are held directly and commonly by the housing (3).

[2] The electric current sensor (1) according to [1], wherein the bus bars (2), the first shield plate (61), and the second shield plate (62) are held to be parallel to each other by the housing (3).

[3] The electric current sensor (1) according to [1] or [2], wherein the housing (3) comprises a rectangular upper wall (31) parallel to the bus bars (2) and a pair of side walls (32) extended in the thickness direction from edges of facing sides of the upper wall (31) as one piece,

wherein the first shield plate (61) is held on a surface opposite to an extending side of the side walls (32) in the upper wall (31),

wherein the second shield plate (62) is held at tip end portions of the side walls (32).

[4] The electric current sensor (1) according to [3], wherein a recess (311) for accommodating the first shield plate (61) is provided at the surface opposite to the extending side of the side walls (32) in the upper wall (31),

wherein a first shield cover (11a) is provided to close an opening of the recess (311) and the first shield cover (11a) holds the first shield plate (61) with being pressed against a bottom surface of the recess (311).

[5] The electric current sensor (1) according to [3] or [4], wherein a step portion (322) is provided at the tip end portion of each of the side walls (32),

wherein the step portion (322) is formed by protruding an outer peripheral portion of the side wall (32) toward a tip end side and recessing an inner peripheral portion of the side wall (32) toward the upper wall (31),

wherein the second shield plate (62) is held by a step surface (322a) as an end surface of a recessed portion of the step portion (322).

[6] The electric current sensor (1) according to [5], wherein a second shield cover (11b) is provided at the tip end portions of the side walls (32) to face the upper wall (31),

wherein the second shield cover (11b) holds the second shield plate (62) with being pressed against the step surface (322a).

[7] The electric current sensor (1) according to any one of [3] to [6], wherein a plurality of notches (321) for inserting the bus bars (2) into the bus bar-holding portion (312) are provided to open toward the tip end side of the side walls (32),

wherein the plurality of notches (321) are spaced from each other in the width direction,

wherein the second shield plate (62) is held by the side walls (32) at both ends in the width direction and the side walls (32) adjacent to each other in the width direction between the plurality of notches (321).

[8] The electric current sensor (1) according to any one of [1] to [7], wherein the magnetic detection element (4) is arranged at a position which is equidistant from the first shield plate (61) and the second shield plate (62).

Although the embodiments of the present invention have been described above, the above described embodiments are not to be construed as limiting the inventions according to the claims. Further, it should be noted that not all the combinations of the features described in the embodiments are indispensable to the means for solving the problem of the invention.

The present invention can appropriately be modified and implemented without departing from the spirit of the present invention. For example, in the above embodiment, the housing 3 and the spacer 7 are configured separately, but the housing 3 and the spacer 7 may be formed integrally as one piece by molding the housing 3 after inserting the bus bars 2.

What is claimed is:

1. An electric current sensor comprising:
bus bars, each of which has a plate shape and flows an electric current to be detected in a length direction;
a housing including a bus bar-holding portion for holding the bus bars with being aligned in a width direction perpendicular to the length direction and a thickness direction of the bus bars;
magnetic detection elements, each magnetic detection element detecting a strength of magnetic field generated by the electric current flowing through a corresponding bus bar; and
a first shield plate and a second shield plate arranged to sandwich the respective bus bars and the magnetic detection elements in the thickness direction, each of the first shield plate and the second shield plate comprising a magnetic material,
wherein both the first shield plate and the second shield plate are held directly and commonly by the housing.

2. The electric current sensor according to claim 1, wherein the bus bars, the first shield plate, and the second shield plate are held to be parallel to each other by the housing.

3. The electric current sensor according to claim 1, wherein the housing comprises a rectangular upper wall parallel to the bus bars and a pair of side walls extended in the thickness direction from edges of facing sides of the upper wall as one piece,
wherein the first shield plate is held on a surface opposite to an extending side of the side walls in the upper wall,
wherein the second shield plate is held at tip end portions of the side walls.

4. The electric current sensor according to claim 3, wherein a recess for accommodating the first shield plate is provided at the surface opposite to the extending side of the side walls in the upper wall,
wherein a first shield cover is provided to close an opening of the recess and the first shield cover holds the first shield plate with being pressed against a bottom surface of the recess.

5. The electric current sensor according to claim 3, wherein a step portion is provided at the tip end portion of each of the side walls,
wherein the step portion is formed by protruding an outer peripheral portion of the side wall toward a tip end side and recessing an inner peripheral portion of the side wall toward the upper wall,
wherein the second shield plate is held by a step surface as an end surface of a recessed portion of the step portion.

6. The electric current sensor according to claim 5, wherein a second shield cover is provided at the tip end portions of the side walls to face the upper wall,
wherein the second shield cover holds the second shield plate with being pressed against the step surface.

7. The electric current sensor according to claim 3, wherein a plurality of notches for inserting the bus bars into the bus bar-holding portion are provided to open toward the tip end side of the side walls,
wherein the plurality of notches are spaced from each other in the width direction,
wherein the second shield plate is held by the side walls at both ends in the width direction and the side walls adjacent to each other in the width direction between the plurality of notches.

8. The electric current sensor according to claim 1, wherein the magnetic detection element is arranged at a position which is equidistant from the first shield plate and the second shield plate
